(19) United States
(12) Patent Application Publication
(10) Pub. No.: US 2021/0296563 A1
(43) Pub. Date: Sep. 23, 2021

(54) PIEZO DRIVE, IN PARTICULAR AS AN AUTOMATIC ACTUATING ELEMENT FOR A VEHICLE COMPONENT

(71) Applicant: BEHR-HELLA THERMOCONTROL GMBH, Stuttgard (DE)

(72) Inventors: Stefan KIRSCH, Soest (DE); Volker DICKE, Bestwig (DE)

(21) Appl. No.: 17/266,052

(22) PCT Filed: Jul. 31, 2019
(86) PCT No.: PCT/EP2019/070684

§ 371 Date: Feb. 4, 2021

(30) Foreign Application Priority Data
Aug. 6, 2018 (DE) 10 2018 119 063.8

(51) Int. Cl. H01L 41/053; H02N 2/04; H01L 41/09

(52) U.S. Cl. CPC H01L 41/053; G06F 3/016; H01L 41/0986; H02N 2/043

(57) ABSTRACT

The piezo drive is provided with a piezo actuator which can be reversibly expanded with respect to its longitudinal extent and has two ends which are averted from one another and also has two lateral sides which are averted from one another. A conversion transmission is coupled to the piezo actuator for converting an expansion and a subsequent contraction of the piezo actuator into in each case a movement which is directed at an angle which is not equal to 0 degrees, in particular of 90° in relation to the longitudinal extent of the piezo actuator. The conversion transmission has an elastic clip which has two receiving legs, which are situated opposite one another and are at a distance from another, and a connecting which extends between said receiving legs and has at least one section which is directed away from the piezo actuator with respect to the position of said piezo actuator or a section which is bent in the direction of said piezo actuator. The piezo actuator is, at its two ends, received by the receiving legs so as to bear against them and the connection leg of the clip is arranged to the side of one of the two lateral sides of the piezo actuator.

The invention relates to a piezo drive which in particular is intended for use as an automatic actuator for a vehicle component and which in particular serves to generate a haptic feedback of an operating device.

Piezo drives are used in a variety of applications. Here, advantage is taken of the length variability of a piezoelectric element in an effective direction when driven electrically, so as to mechanically excite a component or unit to be moved. An application in the automobile industry is the use of a piezo drive to generate a haptic feedback of an operating device. Such an operating device comprises a touch screen or a touch pad, which is mechanically excited temporarily or in a pulse-like manner when a valid manual operation has been detected. In this manner, a haptic feedback is obtained by which the operator receives a tactile response to a valid operation. The invention relates in particular of a piezo actuator with a transmission, which in professional circles is also referred to as a piezo actuator with mechanical amplification.

The length variability of piezo actuators or of piezoelectrically acting elements of such actuators is sufficiently great to be perceived tactilely, which, however, is often insufficient because of the respective application. In order to increase the length variability piezo actuators are implemented which comprise a plurality of stacked piezoelectric elements (hereinafter referred to as piezo element). Such a piezo actuator acts mechanically on a movement conversion structure or a corresponding conversion transmission by which a small length variation of the piezo actuator in the effective direction, which occurs at a comparatively great force, is converted into a large movement with a correspondingly smaller force.

Examples of piezo drives with a conversion transmission are described in DE-U-20 2008 017 833, U.S. Pat. No. 6,246,132, U.S. Pat. No. 4,952,835, WO-A-2017/1762019, U.S. Pat. No. 9,523,294, EP-A-3 056 977, WO-A-2014/164018, WO-A-2016/067831, U.S. Pat. No. 6,465,936, WO-A-2014/096565, US-A-2016/0027263, DE-A-10 2016 116 763, JP-A-2008-287402, EP-A-1 035 015, DE-B-23 05 277, DE-C-42 14 220 and DE-B-199 81 030.

Usually, adhesive technologies are used to connect the piezo actuator with the conversion structure. In mass production, these entail a high effort.

It is an object of the invention to provide a piezo drive having a piezo actuator with mechanical amplification which is improved with respect to its manufacture and susceptibility to errors.

To achieve this object the invention provides a piezo drive. in particular as an automatic actuator for a vehicle component, e.g. for generating a haptic feedback in operating devices, wherein the piezo drive is provided with
a piezo actuator of a piezoelectric material, the piezo actuator having a longitudinal extension between two ends having front faces averted from one another, the longitudinal extension defining an effective direction of the piezo actuator along which the piezo actuator expands and contracts,
a conversion transmission connected with the piezo actuator for converting an expansion and a subsequent contraction of the piezo actuator, which occur in the effective direction of the piezo actuator, into a movement which in each case is directed at an angle different from 0 degrees, in particular an angle of 90 degrees, relative to the longitudinal extension of the piezo actuator,
the conversion transmission comprising an elastic bracket and/or a bracket comprising an elastic material, which comprises two opposite and spaced apart receiving legs and a connection leg extending therebetween which has at least one section which, relative to the position of the piezo actuator, is arched away or toward the same, and
the piezo actuator being received at its two ends by the receiving legs in adhesive-free contact therewith, and the connection leg of the bracket being arranged to the side of the piezo actuator.

The piezo actuator of the drive according to the invention, when driven electrically, is reversibly expandable with respect to its effective direction and comprises two ends averted from one another and, between these, one or a plurality of piezo elements stacked one open the other. By driving the piezo element or elements electrically the piezo actuator expands along its effective direction. When the drive voltage is deactivated, the piezo actuator contacts again due to its elasticity. As a piezoelectrically active material ceramics have prevailed. However, printable piezoelectric polymers may also be used which are presently still researched.

The piezo actuator is coupled with a (movement) conversion transmission which converts an expansion and a subsequent contraction of the piezo actuator into (opposite) movements which are preferably directed at 90° relative to the longitudinal extension of the piezo actuator and thus at right angles to the direction in which the piezo actuator changes its length. Angles other than 90° between the direction of length variation and the movement direction of the conversion transmission, i.e. angles between 90 and 0°, are also structurally possible. In the simplest case, the conversion transmission is implemented by a bracket that is configured to be elastic. The elasticity of the bracket may be realized either through structural measures or through the choice of material. At least in a section along the piezo actuator, the bracket extends at a varying distance from the same. The bracket comprises two opposite and spaced apart receiving legs between which a connection leg of the bracket extends. Thus, in side view, the bracket is essentially U-shaped. In its connection leg, the above mentioned section is located in which the distance of the connection leg from a longitudinal axis extending between the receiving legs of the bracket varies, i.e. increases or alternatively decreases starting from a first distance value (distance from the longitudinal axis of the piezo actuator).

The piezo actuator is held clamped between the receiving legs of the bracket of the conversion transmission. Here, the piezo actuator abuts on the receiving legs by both of its ends or is received thereby, so that the connection leg of the bracket extends substantially laterally beside the piezo actuator, and does so at a distance from the same that varies in particular in the above mentioned section. If, upon being driven electrically the piezo actuator expands in the effective direction, the elastic bracket will stretch as a result, so that the distance of said (distance variation) section from the piezo actuator changes. This change is then used to move an element, a component or a unit or the like.

The shape of the (distance variation) section of the connection leg of the bracket between the receiving legs of the same (which may possibly comprise receiving elements) enclosing the ends of the piezo actuator determines the amount of the movement stroke (and the orientation of the movement) which the connection section is subjected to and the size of the ratio of the longitudinal expansion of the piezo actuator and the movement stroke. In this context, it is important e.g. under which angle portions of the (distance variation) section extend relative to the longitudinal axis of the piezo actuator (e.g. a trapezoidal or a U-shaped or a circular arc shaped course of the section).

According to the invention the piezo actuator is not adhesively connected to the receiving legs. Rather, the piezo actuator is preferably received by the receiving legs in a substantially positive manner and abuts thereon without being connected to them by adhesion. This applies to the front faces of the piezo actuator. If necessary, the sections of the circumferential surface of the piezo actuator that adjoin the front faces also abut on the receiving legs of the bracket or brackets. For example, the receiving legs can comprise receiving elements which have a corresponding receiving recess into which the ends of the piezo actuator are inserted.

Due to the inventive adhesive-free coupling of the ends of the piezo actuator with the receiving legs of the conversion transmission, it is achieved that the piezo actuator is protected against tensile forces to which piezoceramic material generally reacts very sensitively. If the piezo actuator implemented according to the invention were to contract inadvertently, starting from the rest position in which it is not electrically driven, the invention would allow this without any risk, since, with regard to contraction, there is no fixed connection between the piezo actuator and the receiving legs of the bracket. Moreover, this provides protection against external improper forces that can thus not cause the piezo actuator and the piezo elements to be pulled apart.

In a further advantageous embodiment, it may be provided that the conversion transmission comprises a further connection leg that is opposite the other connection leg of the bracket and is also arcuate in shape, whereby both connection legs are substantially symmetric to one another. Thus, the further connection leg comprises at least one section along its extension between the receiving legs, in which the distance of the further connection leg first increases—or alternatively decreases—from a third distance value to a fourth distance value along its extension between the receiving legs from the longitudinal axis extending between the receiving legs. In this embodiment of the invention the conversion transmission has two connection legs arranged on opposite lateral sides of the piezo actuator, each leg having a distance from the piezo actuator which changes with respect to the piezo actuator within at least one section. Thus, the conversion transmission comprises a (frame) bracket extending around the piezo actuator, in which the piezo actuator is arranged, with the ends thereof abutting on the frame, i.e. on the receiving legs of the brackets. The conversion transmission may comprise receiving elements in the region of these receiving legs, which elements are fit into or received by the same. However, the receiving legs themselves could also be formed e.g. as the ends of the piezo actuator on receiving elements that engage around all sides.

The two connecting legs of the bracket of the conversion transmission according to the above-mentioned development of the invention may extend symmetrically to one another, the central longitudinal axis of the piezo actuator in this case forming the axis of symmetry, or may as well not extend symmetrically to one another.

Depending on the configuration and the design, as well as on the course of the connection legs or the connection leg of the bracket within said distance variation section, the direction and the movement stroke are defined into which the movement of the length variation of the piezo actuator is converted.

In a suitable further embodiment of the invention, it may be provided that the bracket is formed with an oval, lenticular or elliptical shape, with the receiving legs being arranged at the ends of the longer axis of the oval or the lens or the ellipse and defining the shorter axis of the oval, lenticular or elliptical bracket with respect to the sections of the connection legs that change their distances from the longitudinal axis. With an ellipse or lens or an oval, a major axis and a minor axis can be defined. The major axis is the longer one of the two diameters defined by the oval, lenticular or elliptical shape. The piezo actuator either extends along the major axis or the minor axis of the elliptical or the oval shape. Correspondingly, the length variation sections of the two brackets are then situated along the minor axis or along the major axis.

As already mentioned above the two receiving legs of the bracket may comprise receiving elements into the receiving recesses of which the ends of the piezo actuator are inserted. These receiving elements are advantageously joined to the receiving legs of the brackets by means of mechanical fastening elements such as screws, pins, rivets or the like.

It is advantageous if the manufacture of the conversion transmission requires no die casting or milling operations. In this respect, it is advantageous to make the conversion transmission from a punched, cut or lasered metal. Here, it is advantageously appropriate for the bracket to be designed as a metal strip element having two ends averted from one another, which element is bent in a C-shape when seen from the side, wherein an intermediate section located in the longitudinal direction of the metals strip element forms one receiving leg of the bracket and the two ends of the metal strip element forms the other receiving leg of the bracket or a receiving element is arranged between these two ends of the metal strip element which forms the receiving leg of the bracket. Two opposite lugs may be arranged to the side of the intermediate section which, angled in the same direction, together with the intermediate section form a receptacle abutting the one end of the piezo actuator on all sides. Such lugs may also be provided at one of the ends of the metal strip element, where they form a receptacle for the other end at the piezo actuator at the other receiving leg of the bracket, after being angled in the same direction.

As already mentioned above, the piezo actuator should be held clamped in the conversion transmission or the bracket, so as to stretch the bracket already at the slightest length variations. In this respect, it is advantageously provided that the bracket has a tensioning element arranged at one of the two receiving legs and can be positioned and fixed in its position on the receiving leg to define its abutment on the front face of one end of the piezo actuator, as well as the pressing force applied on the piezo actuator in the direction of the course of the connection axis,

This tensioning element advantageously is an adjusting screw whose threaded shaft end acts on one of the front face ends of the piezo actuator or acts on a receiving element receiving this end, so as to move/urge the same in a direction against the piezo actuator.

As mentioned above, the conversion transmission may comprise a correspondingly bent oval, lenticular or elliptical metal strip. The metal strip is bent with respect to its intermediate section. This intermediate section then forms a receptacle for the one end of the piezo actuator. The free ends of the metal strip element are bent so as to form a second receptacle for the other end of the piezo actuator. These two ends of the metal strip element can be connected with each other or held together by means of a screw. In an advantageous embodiment of the invention this screw may then also perform the function of the above described adjusting screw for applying a pretension on the piezo actuator.

The invention will be described in more detail hereunder with reference to two embodiments and with reference to the drawings. Specifically, the Figures show:

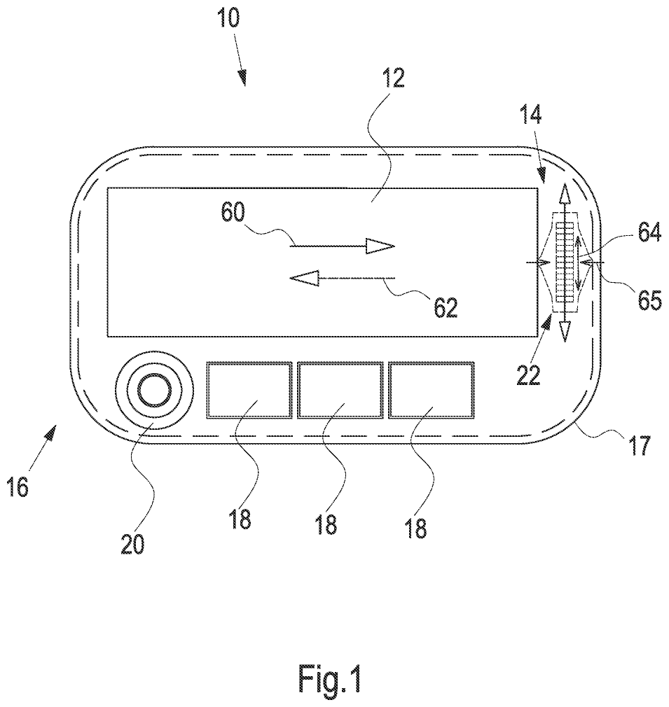

FIG. 1 a schematic front view of a vehicle operating unit comprising a touch pad or touch screen which is excited in a pulse-like manner by a piezo actuator to generate a haptic feedback and thus to provide a tactile response to a manual touch input,

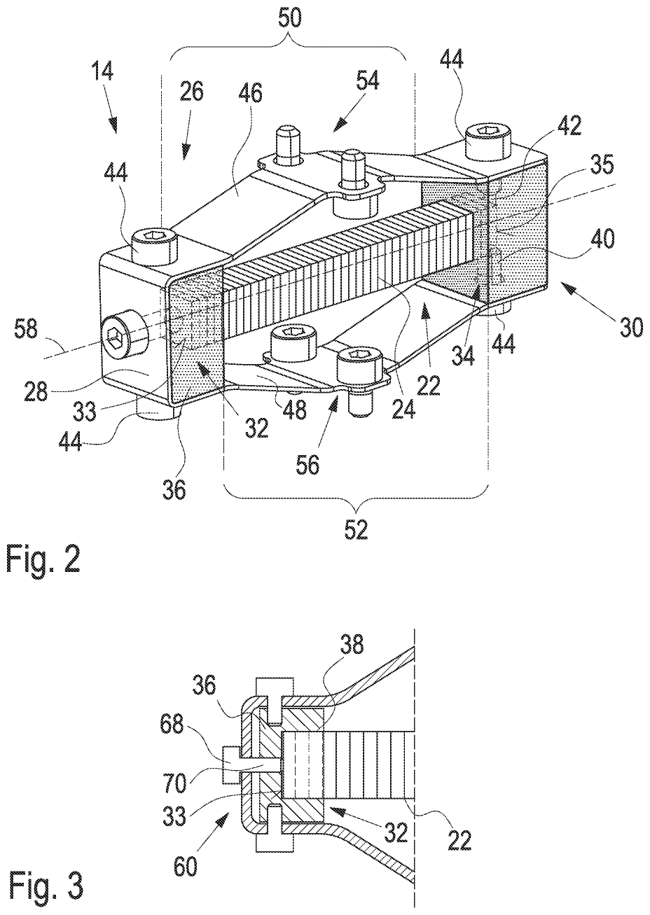

FIGS. 2 to 5 different views of the components of a first embodiment of a piezo drive usable in the operating unit of FIG. 1, and

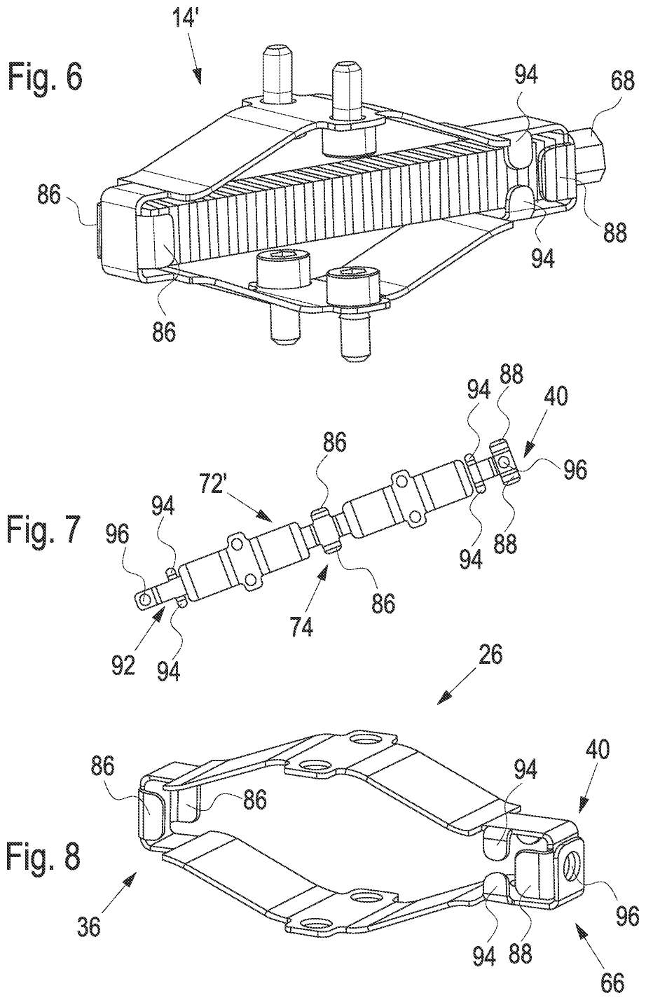

FIGS. 6 to 8 different views of components of a second embodiment of a piezo drive usable in the operating unit of FIG. 1.

FIG. 1 is a front view of an operating unit 10 for a vehicle, in which the operating element 12 is designed as a touch screen or a touch pad at which a valid operating command input is fed back tactilely by a pulse-like mechanical excitation (haptic feedback). For this purpose, the operating unit 10 comprises a piezo drive 14 which is arranged and effective e.g. between the housing wall 17 of the housing 16 of the operating unit 10 and its operating element 12. Besides the operating element 12 providing a touch-sensitive input option, the operating unit 10 may e.g. comprise other operating elements such as buttons 18 and/or a rotary adjuster 20.

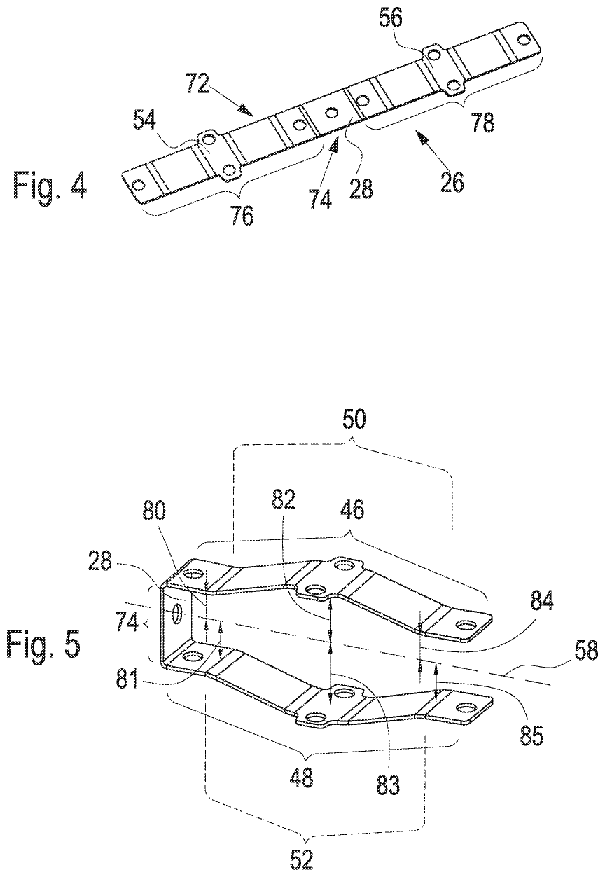

A first embodiment of the piezo drive 14 is illustrated in FIGS. 2 to 5. The piezo drive 14 is provided with a piezo actuator 22 which comprises a stack of individual piezo elements 24. The electric contacting of these piezo elements 24 is not illustrated in the Figures for the sake of clarity. The piezo drive 14 further comprises a metal bracket 26 which in this embodiment is provided with two receiving legs 28, 30 by which the ends 32, 34 of the piezo actuator 22 are received by their front faces 33, 35 which are averted from one another. For this purpose, a receiving element 36 abuts on the first receiving leg 28, which element comprises a receiving recess 38 for the respective end 32 of the piezo actuator 22, as can be seen in particular in FIG. 4. The other receiving leg 30 is formed as another receiving element 40 which also comprises a receiving recess 42 for the other end 34 of the piezo actuator 22. Both receiving elements 36, 40 are fastened to the bracket 26 by means of screws 44.

In this embodiment two connection legs 46, 49 extend between the receiving legs 28, 30 of the bracket 26, of which the connection leg 46 is arranged on one lateral side of the piezo actuator 22, while the other connection leg 48 is arranged opposite the previously mentioned first connection leg 46 on the opposite lateral side of the piezo actuator 22. The special feature of the two connection legs 46, 48 is that each has a connection section 50 or 52, respectively, within which the distance of the respective connection legs 46 from the piezo actuator 22 changes, i.e., in the present embodiment, increases and then decreases again. Thus, each connection section 50 comprises a vertex region 54, 56, so to speak, which is spaced farthest from the piezo actuator. The two connection legs 46, 48 thus extend bulged outward with respect to the piezo actuator 22 and seen from the same, but could as well be bulged in the opposite direction. Further, it is possible that one connection leg is convex, i.e. bulged away from the piezo actuator 22, whereas the other connection leg is concave, i.e. bulged towards the piezo actuator 22.

Within the vertex regions 54, 56, the bracket 26 is fastened to the operating element 12 on the one hand and to the housing 16 on the other hand, as indicated in FIG. 1. For example, screws 57 serve this purpose.

When an electric voltage is applied to the piezo actuator 22 the same expands in the longitudinal direction, i.e. in the extension direction of the axis 58. As a result, the sections 50, 52 of the connection legs 46, 48 move towards the piezo actuator 22. Thereby, with reference to the application shown in FIG. 1, the operating element 12 would thus be moved in the direction of the arrow 60 to then move back in the direction of the arrow 62, when voltage is no longer applied to the piezo actuator 22. During this process, the piezo actuator 22 thus first expands and the connection legs 46, 48 move towards each other (see arrows 64 and 65 in FIG. 1) and then move away from each other again when voltage is no longer applied. The bracket 26 having the connection legs 46, 48 thus forms a movement conversion transmission 70.

The advantage of the inventive structure of the piezo drive 14 is that at its two ends 32, 34, the piezo actuator 22 abuts on the receiving elements 36, 40 in the receiving recesses 38, 42 without being glued thereto. In the electrically not excited state of the piezo actuator 22, the ends 32, 34 of the piezo actuator 22 should be in contact with the bottoms of the receiving recesses 38, 42 and the piezo actuator 22 should be held clamped in the bracket 26 when in its rest position respectively. This purpose is served by a tensioning element 66 which in this embodiment is in the form of a tensioning screw 68 that, as shown for example in FIG. 4, abuts on one of the ends (in this embodiment on the end 32) of the piezo actuator 22 by its shaft end 71.

The structure of the bracket 26 can be seen in FIGS. 4 and 5. In a simple manner, this bracket 26 is designed as a metal strip element 71 whose intermediate section 74, seen in the longitudinal extension, forms the first receiving leg 28. The sections 76, 78 for the two connection legs 46, 48 are located on either side of this intermediate section 74. Within these two sections 76, 78, the region for the vertex region 54, 56 is then located as well. The advantage of the design of the bracket 26 corresponding to FIGS. 4 and 5 is the possibility of manufacturing the bracket as a punched metal part. Thus, no casting or milling operations are required to manufacture the bracket 26.

As can be seen in particular with reference to FIGS. 2 and 5, the bracket 26 essentially has the shape of an ellipse or an oval. Within the connection leg 46, the connection section 50 thereof extends starting from a first distance value (see the distance of the connection section 50 from the piezo actuator 22 at 80 in FIG. 5) up to a greater second distance value (see the distance of the vertex region 54, 56 from the piezo actuator 22 at 82 in FIG. 5), which is in the region of the vertex region 54, 56 of the respective connection leg, to decrease from there to a smaller further distance value (see again in FIG. 5 at 84 the distance which in this embodiment is equal to the distance value at 80) which may e.g. equal to the first distance value. Thereby, e.g., a symmetric design of the bracket 26 is obtained if both connection legs 46, 48 are shaped correspondingly, which, however, is not mandatory for the purposes of the invention. The two connection legs 46, 48 could also be shaped to be not symmetric with respect to each other. As such, the distance of the connection leg 48 at the beginning of the connection section 52 (see FIG. 5 at 81) could be equal to or different from the distance value 80 of the connections section 50. The (fourth) distance value 83 in the vertex region 56 (see FIG. 5 at 83) may be equal to or different from the distance 82. The distance value 85 of the connection section 52 may be different from the distance value 81 of the connection section 50.

In FIGS. 6 to 8 illustrates a second embodiment of a piezo drive 14′ according to the invention. As far as individual parts of this piezo drive 14′ are similar in structure or function to the elements of the piezo drive 14 in FIGS. 2 and 5, they are identified in FIGS. 6 to 8 by the same reference numerals as in FIGS. 2 to 5.

As illustrated in the embodiment in FIGS. 2 to 5, the bracket 26 of the piezo drive 14′ in FIGS. 6 to 8 is also designed as a bent metal strip element 72. Whereas, however, in the embodiment in FIGS. 2 to 5 the receiving legs are provided with separate receiving elements 36, 40, these receiving elements 36, 40 are formed using individual bendable lugs of the metal strip element 72 in the embodiment in FIGS. 6 to 8. The metal strip element 72 has two laterally arranged bending lugs 86 in the intermediate section 74. Two further bending lugs 88 are formed at one of the two ends 90, 92 of the metal strip element 72. At both ends 90, 92 still further, in this embodiment smaller bending lugs 94 are located, as illustrated in FIG. 7.

In the fully bent state and thus in the final state of the metal strip element 72 the same has the shape of the bracket 26 according to FIGS. 6 and 7. It is evident from FIG. 8 how the individual bending lugs are shaped in this case. The two ends 90, 92 of the metal strip element 72 are further each provided with one hole 96. ion the bent sate, these two holes 96 are aligned by the two ends 90, 92 of the metal strip element lying one above the other, as illustrated in FIG. 8. A tensioning screw 68 extends through the aligned holes 96 as a tensioning element 66 which is in threaded engagement with, e.g., a screw nut (not illustrated) that rests on the inside of the receiving leg 30 or with an element having a female threaded bore for the tensioning screw 68.

In conclusion, it should be noted that the brackets or metal strips are provided with stampings or crimps at the bending lines (see, e.g., FIGS. 2 and 6) which act in the manner of hinges and can thus be formed like film hinges.

### LIST OF REFERENCE NUMERALS

10 operating unit

12 operating element

14 piezo drive

14′ piezo drive

16 housing

17 housing wall

18 buttons

20 rotary adjuster

22 piezo actuator

24 piezoelectric element (piezo element)

26 metal bracket

28 receiving leg

30 receiving leg

32 end of piezo actuator

33 front face of piezo actuator

34 end of piezo actuator

35 front face of piezo actuator

36 receiving element

38 receiving recess

40 receiving element

42 receiving recess

44 screws

46 connection leg

48 connection leg

50 connection section

52 connection section

54 vertex region

56 vertex region

57 screws

58 axis

60 arrow

62 arrow

64 arrow

65 arrow

66 tensioning element

68 tensioning screw

70 conversion transmission

71 shaft end

72 metal strip element

72′ metal strip element

74 intermediate section

76 sections

78 sections

80 first distance value

81 third distance value

82 second distance value

83 fourth distance value

84 further distance

85 further distance

86 bending lugs

88 bending lugs

90 ends

92 ends

94 bending lugs

96 hole

### Prior Art Documents

DE-U-20 2008 017 833

DE-A-10 2016 116 763

DE-B-23 05 277

DE-C-42 14 220

DE-B-199 81 030

EP-A-1 035 015

EP-A-3 056 977

WO-A-2014/096565

WO-A-2017/1762019

WO-A-2014/164018

WO-A-2016/067831

US-A-2016/0027263

U.S. Pat. No. 6,246,132

U.S. Pat. No. 4,952,835

U.S. Pat. No. 9,523,294

U.S. Pat. No. 6,465,936

JP-A-2008-287402

1-16. (canceled)

17. A piezo drive in particular as an automatic actuator for a vehicle component, e.g., for generating a haptic feedback in operating devices, wherein the piezo drive is provided with
a piezo actuator of a piezoelectric material, the piezo actuator having a longitudinal extension between two ends each having a front face averted from one another, the longitudinal extension defining an effective direction of the piezo actuator along which the piezo actuator expands and contracts,
a conversion transmission connected with the piezo actuator for converting an expansion and a subsequent contraction of the piezo actuator, which occur in the effective direction of the piezo actuator, into a movement which in each case is directed at an angle different from 0 degrees, in particular an angle of 90 degrees, relative to the longitudinal extension of the piezo actuator,
the conversion transmission comprising an elastic bracket and/or a bracket comprising an elastic material, which comprises two opposite and spaced apart receiving legs and a connection leg extending therebetween which has at least one section which, relative to the position of the piezo actuator, is arched away or toward the same, and
the piezo actuator being received at its two ends by the receiving legs in adhesive-free contact therewith, and the connection leg of the bracket being arranged to the side of the piezo actuator.

18. The piezo drive according to claim 17, wherein the distance of the connection leg increases—or alternatively decreases—along its extension between the receiving legs of the bracket, starting from a first distance value to a second distance value.

19. The piezo drive according to claim 18, wherein the distance of the connection leg again decreases—or alternatively increases—along its extension between the receiving legs of the bracket, starting from the second distance value and in particular up to the first distance value.

20. The piezo drive according to claim 17, wherein the conversion transmission comprises a further connection leg which is opposite the other connection leg of the bracket and is also of an arched design.

21. The piezo drive according to claim 20, wherein the two connection legs are essentially symmetrical with respect to each other.

22. The piezo drive according to claim 20, wherein the distance of the further connection leg increases—or alternatively decreases—along its extension between the receiving legs of the bracket, starting from a third distance value to a fourth distance value.

23. The piezo drive according to claim 22, wherein the distance of the further connection leg of the bracket from the longitudinal axis extending between the receiving legs again decreases—or alternatively increases—along its extension between the receiving legs of the bracket, starting from the fourth distance value up to the third distance value.

24. The piezo drive according to claim 18, wherein the two connection legs are symmetric with respect to the longitudinal axis extending between the two receiving legs or that the first distance value is different from the third distance value and, if applicable, the second distance value is different from the fourth distance value, if applicable.

25. The piezo drive according to claim 17, wherein the bracket is designed to be oval, lenticular or elliptical in shape, the receiving legs being arranged at the ends of the longer axis of the oval, the lens or the ellipse and the shorter axis of the oval, lenticular or elliptical bracket being situated in the region of the sections of the connection legs which change with respect to their distances from the longitudinal axis.

26. The piezo drive according to claim 17, wherein the receiving legs of the bracket enclose the ends of the piezo actuator on at least two sides verted from each other and in particular on all sides.

27. The piezo drive according to claim 26, wherein at least one of the receiving legs and in particular both receiving legs comprises receiving elements connected with the receiving leg or legs by fastening means.

28. The piezo drive according to claim 17, wherein the bracket is designed as a metal strip element having two opposite ends, which in side view is bent in a C-shape, wherein an intermediate section situated in the longitudinal extension of the metal strip element forms one receiving leg of the bracket and the two ends of the metal strip element form the second receiving leg of the bracket or a receiving element forming the receiving leg of the bracket is arranged between these two ends of the metal strip element.

29. The piezo drive according to claim 17, wherein the bracket comprises a tensioning element which is arranged at one of the two receiving legs and can be positioned and fixed in its position at the receiving leg to define its abutment on the front face of one of the ends of the piezo actuator as well as the pressing force applied in the process on the piezo actuator in the direction of the extension of the axis of the piezo actuator.

30. The piezo drive according to claim 29, wherein the tensioning element is an adjusting screw or can be positioned by an adjusting screw.

31. The piezo drive according to claim 28, wherein the adjusting screw additionally also interconnects the two ends of the metal strip element bent in the shape of a bracket, which ends overlap each other and form an abutment leg of the bracket.

32. The piezo drive according to claim 17, wherein the piezo actuator comprises a piezoelectric element or a plurality of piezoelectric elements stacked in the effective direction of the piezo actuator.
